(19) United States
(12) Patent Application Publication
(10) Pub. No.: US 2022/0069271 A1
(43) Pub. Date: Mar. 3, 2022

(54) BATTERY

(71) Applicant: Shenzhen Eigate Technology Co., Ltd., Shenzhen (CN)

(72) Inventor: Tuanfang LIU, Shenzhen (CN)

(21) Appl. No.: 17/005,356

(22) Filed: Aug. 28, 2020

(51) Int. Cl. H01M 2/20; H01H 13/14; H01M 2/10; H01M 10/42; A24F 40/60; A24F 40/50

(52) U.S. Cl. CPC H01M 2/20; H01H 13/14; H01M 2/1055; H01M 2220/30; A24F 40/60; A24F 40/50; H01M 10/425

(57) ABSTRACT

A battery including a power switching component provided with a button. When in use, the output power of the battery is switchable by consecutively pressing the button.

### BACKGROUND

The disclosure relates to a battery for electronic cigarettes.

Known batterie for electronic cigarettes have no power switching function.

### SUMMARY

The disclosure provides a battery comprising a power switching component provided with a first button, wherein when in use, an output power of the battery is switchable by consecutively pressing the first button.

The power switching component further comprises a control panel, a support, and a battery cell; an output end of the battery cell is connected to an input end of the control panel to supply power to the control panel; the support is transparent and disposed on the control panel to support the first button; the first button is disposed on the support; when in use, the output power of the battery is switchable when the first button is consecutively pressed three times.

The battery further comprises a switch control unit provided with a second button; when in use, the battery is switchable between an on state and an off state when the second button is consecutively pressed for several times.

The first button and the second button are the same; a preset number of times of pressing the first/second button for switching the output power of the battery is different from that of pressing the first/second button for switching the on/off state of the battery; and a preset number of times of pressing the first/second button for switching on the battery is the same as that for switching off the battery.

The battery is switchable between an on state and an off state when the second button is consecutively pressed five times.

The power switching component and the switch control unit are disposed on the control panel, and the control panel comprises a circuit configured to control the power switching component and the switch control unit.

The battery comprises the power switching component, and the output power of the battery is switchable by consecutively pressing the first button three times. The battery further comprises the switch control unit provided with the second button; when in use, the battery is switchable between an on state and an off state when the second button is consecutively pressed for 5 times. That is, when the battery is working, consecutively press the second button 5 times, the battery is switched off and no power output, and vice versa. Thus, when in nonuse, the battery has no output, so it is energy-saving and safe.

### BRIEF DESCRIPTION OF THE DRAWINGS

FIG. 1 is an exploded view of a battery according to one embodiment of the disclosure;

FIG. 2 is a schematic diagram of a battery according to embodiment of the disclosure; and

FIG. 3 is a sectional view of a battery according to one embodiment of disclosure.

### DETAILED DESCRIPTION

To further illustrate, embodiments detailing a battery are described below. It should be noted that the following embodiments are intended to describe and not to limit the disclosure.

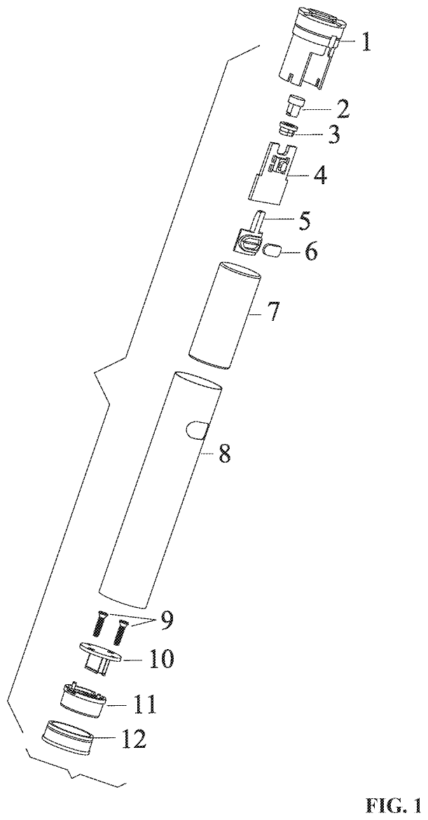

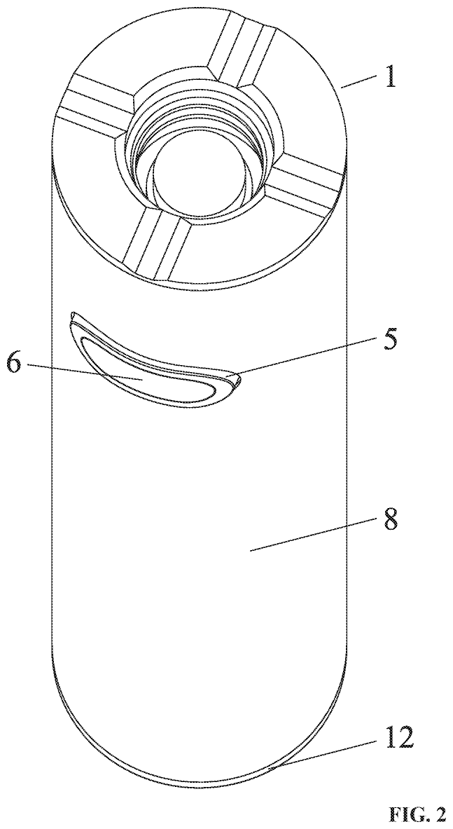

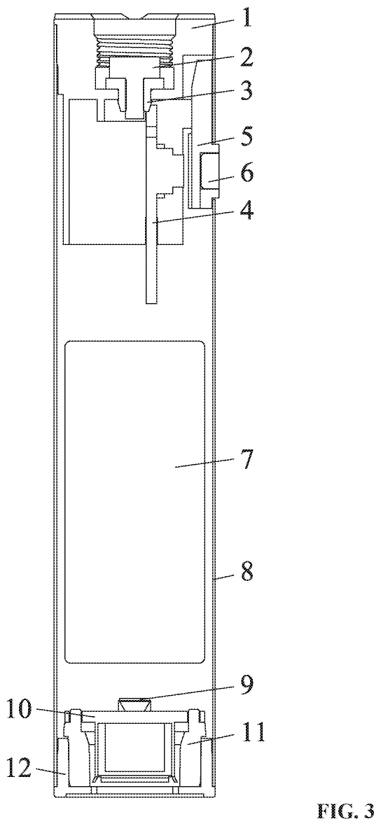

As shown in FIGS. 1-3, a battery comprises a copper threaded ring 1, a battery electrode 2, a silicone ring 3, a control panel 4, a support 5, a first button 6, a battery cell 7, a battery cartridge 8, a bolt 9, a USB board 10, a USB base 11, and a bottom cover 12. The silicone ring 3 is disposed in the copper threaded ring 1. The battery electrode 2 is disposed in the silicone ring 3. The control panel 4 is disposed in the copper threaded ring 1. The output end of the battery cell 7 is connected to the input end of the control panel 4 to supply power to the control panel 4. The battery cell 7 is disposed in the battery cartridge 8. The support 5 is transparent and disposed on the control panel 4 and the first button 6 is fixed on the support 5. The copper threaded ring 1 is disposed on the top of the battery cartridge 8. The USB board 10 is fixed on the USB base 11 via the bolt 9. The USB base 11 is disposed in the bottom cover 12. The bottom cover 12 is disposed on the bottom of the battery cartridge 8.

The control panel 4 comprises a power switching component provided with the first button and a switch control unit provided with a second button. When in use, the output power of the battery is switchable by consecutively pressing the first button three times; and the battery is switchable between an on state and an off state when the second button is consecutively pressed for 5 times.

The following advantages are associated with the battery of the disclosure:

1. The output power of the battery is switchable by consecutively pressing the first button three times. Thus, the battery is multifunctional.

2. The battery is switchable between an on state and an off state when the second button is consecutively pressed for 5 times. Thus, when in nonuse, the battery has no output, so it is energy-saving and safe.

It will be obvious to those skilled in the art that changes and modifications may be made, and therefore, the aim in the appended claims is to cover all such changes and modifications.

What is claimed is:

1. A battery, comprising: a power switching component provided with a first button, wherein when in use, an output power of the battery is switchable by consecutively pressing the first button.

2. The battery of claim 1, wherein the power switching component further comprises a control panel, a support, and a battery cell; an output end of the battery cell is connected to an input end of the control panel to supply power to the control panel; the support is transparent and disposed on the control panel to support the first button; the first button is disposed on the support; when in use, the output power of the battery is switchable when the first button is consecutively pressed three times.

3. The battery of claim 1, further comprising a switch control unit provided with a second button; when in use, the battery is switchable between an on state and an off state when the second button is consecutively pressed for several times.

4. The battery of claim 2, further comprising a switch control unit provided with a second button; when in use, the battery is switchable between an on state and an off state when the second button is consecutively pressed for several times.

5. The battery of claim 3, wherein the first button and the second button are the same; a preset number of times of pressing the first/second button for switching the output power of the battery is different from that of pressing the first/second button for switching the on/off state of the battery; and a preset number of times of pressing the first/second button for switching on the battery is the same as that for switching off the battery.

6. The battery of claim 4, wherein the first button and the second button are the same; a preset number of times of pressing the first/second button for switching the output power of the battery is different from that of pressing the first/second button for switching the on/off state of the battery; and a preset number of times of pressing the first/second button for switching on the battery is the same as that for switching off the battery.

7. The battery of claim 3, wherein the battery is switchable between an on state and an off state when the second button is consecutively pressed five times.

8. The battery of claim 4, wherein the battery is switchable between an on state and an off state when the second button is consecutively pressed five times.

9. The battery of claim 7, wherein the power switching component and the switch control unit are disposed on the control panel, and the control panel comprises a circuit configured to control the power switching component and the switch control unit.

10. The battery of claim 8, wherein the power switching component and the switch control unit are disposed on the control panel, and the control panel comprises a circuit configured to control the power switching component and the switch control unit.
